(19) United States
(12) Patent Application Publication
(10) Pub. No.: US 2018/0063388 A1
(43) Pub. Date: Mar. 1, 2018

(54) LENS ASSEMBLY AND MANUFACTURING METHOD THEREOF

(71) Applicants: LITE-ON ELECTRONICS (GUANGZHOU) LIMITED, Guangzhou (CN); Lite-On Technology Corporation, Taipei (TW)

(72) Inventor: Wen-Liang Hsu, Taipei (TW)

(73) Assignees: LITE-ON ELECTRONICS (GUANGZHOU) LIMITED, GUANGZHOU (CN); Lite-On Technology Corporation, Taipei (TW)

(21) Appl. No.: 15/353,740

(22) Filed: Nov. 17, 2016

(30) Foreign Application Priority Data
Aug. 29, 2016 (CN) 201610750096.2

(51) Int. Cl. H04N 5/225; G02B 7/02; G02B 13/00; H01L 27/146

(52) U.S. Cl. CPC H04N 5/2254; G02B 7/025; H01L 27/14685; H04N 5/2252; H04N 5/2253; G02B 13/001

(57) ABSTRACT

A lens assembly including a lens module, a housing, a first adhesive, and a circuit board module is provided. The lens module has a top portion and a stand extending out of the top portion and passing through the housing, so that the stand is assembled to the circuit board module. The top portion is connected to an upper side of the housing. The housing is located between the top portion and the circuit board module. The stand, the housing, and the circuit board module are fixed together by the first adhesive. A manufacturing method of the lens assembly is also provided.

### CROSS-REFERENCE TO RELATED APPLICATION

This application claims the priority benefit of China application no. 201610750096.2, filed on Aug. 29, 2016. The entirety of the above-mentioned patent application is hereby incorporated by reference herein and made a part of this specification.

### Field of the Invention

The invention relates to a lens assembly and a manufacturing method thereof.

### Description of Related Art

With the progress of the technology, electronic apparatuses are designed to be characterized by compactness, light weight, and portability, such that users can do portable business or entertainment through the electronic apparatuses at anytime and anywhere. For instance, image capturing apparatuses have been extensively applied in diverse fields, e.g., on smart phones, tablet PCs, wearable apparatuses, and other portable electronic apparatuses. The image capturing apparatuses featuring small volume and portability allow users to capture images and store the captured images at all time and everywhere.

In general, a lens assembly of the image capturing apparatus mainly includes an external lens barrel, an optical lens assembled in the lens barrel, and a sensor device. The optical performance of the lens assembly is directly affected by the optical design of the optical lens and a tolerance of the relative position between the optical lens and the sensor device, and the optical performance of the lens assembly would be better when the tolerance is small.

Since the lens assembly of the image capturing apparatus become smaller and smaller, it is difficult to assemble the lens assembly of the image capturing apparatus. Therefore, it is an important object to provide a lens assembly with good optical performance that has simply structure and can be easily manufactured.

### SUMMARY OF THE INVENTION

The invention provides a lens assembly and a manufacturing method thereof. The lens assembly has a simple structure and can be assembled in a simplified manner, and the resultant lens assembly can have the enhanced optical performance and structural strength.

In an embodiment of the invention, a lens assembly includes a lens module, a housing, a first adhesive, and a circuit board module. The lens module has a top portion and a stand that extends from the top portion. The stand of the lens assembly passes through the housing, and the top portion is connected to an upper edge of the housing. The stand is assembled to the circuit board module by passing through the housing, such that the housing is located between the top portion and the circuit board module. The stand, the housing, and the circuit board module are fixed together by the first adhesive.

In an embodiment of the invention, a manufacturing method of a lens assembly includes arranging a stand of a lens module to pass through the housing, wherein a top portion of the lens module is connected to an upper edge of the housing, and the stand of the lens module leans against a circuit board module. The manufacturing method further includes fixing the stand, the housing, and the circuit board module together by adhering a first adhesive through an underfill packaging technique.

According to an embodiment of the invention, the lens assembly further includes a second adhesive disposed between the top portion of the lens module and the upper edge of the housing.

According to an embodiment of the invention, the circuit board module includes a circuit board, and a gap is formed between a lower edge of the housing and the circuit board. The first adhesive is filled into an attaching space formed by the stand, the housing, and the circuit board through the gap.

According to an embodiment of the invention, the circuit board module further includes an image sensor disposed on the circuit board. The top portion of the lens module faces the image sensor through a hole of the housing. The image sensor is disposed in the attaching space.

According to an embodiment of the invention, an orthogonal projection of the stand on the circuit board module has an open profile.

According to an embodiment of the invention, the stand includes a plurality of pillars extending from the top portion, and the circuit board module has a plurality of blind holes. The pillars are respectively assembled into the blind holes.

According to an embodiment of the invention, an area located on the circuit board module and surrounded by the pillars is filled with the first adhesive.

According to an embodiment of the invention, the stand is a wall extending from the top portion. The circuit board module has a blind slot. The wall is correspondingly assembled to the blind slot.

According to an embodiment of the invention, the stand has a breach, and an area located on the circuit board module and surrounded by the stand is filled with the first adhesive through the breach.

According to an embodiment of the invention, the manufacturing method further includes arranging an image sensor on a circuit board through a ball grid array (BGA) technique to form the circuit board module.

According to an embodiment of the invention, when the stand passes through the housing, the top portion and the upper edge of the housing are adhered by a second adhesive.

According to an embodiment of the invention, the top portion and the upper edge of the housing are adhered by the second adhesive through a pre-curing technique.

According to an embodiment of the invention, the stand includes a plurality of pillars extending from the top portion, and the manufacturing method further includes filling the first adhesive into an area located on the circuit board module and surrounded by the pillars when the underfill packaging technique is performed.

According to an embodiment of the invention, the stand has a breach, and the manufacturing method further includes filling the first adhesive into an area located on the circuit board module and surrounded by the stand through the breach when the underfill packaging technique is performed.

In view of the above, according to the previous embodiments, the lens assembly has the stand that can pass through the housing and can be assembled to the circuit board module. Hence, the lens module, the housing, and the circuit board module can be fixed simultaneously by the first adhesive. Thereby, assembly tolerance resulting from stacking components can be effectively prevented, and the assembly process can be effectively simplified. As a result, the lens assembly with the simple structure can have favorable optical performance and structural strength.

To make the above features and advantages of the invention more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view illustrating a lens assembly according to an embodiment of the invention.

FIG. 2 is an exploded view illustrating the lens assembly in FIG. 1.

FIG. 3 is a lateral view illustrating the lens assembly in FIG. 1.

FIG. 4 is an exploded view illustrating a lens module according to another embodiment of the invention.

FIG. 5 is a schematic view illustrating some components of the lens assembly in FIG. 4.

FIG. 6 is a flowchart showing a manufacturing method of a lens assembly according to an embodiment of the invention.

### DESCRIPTION OF EMBODIMENTS

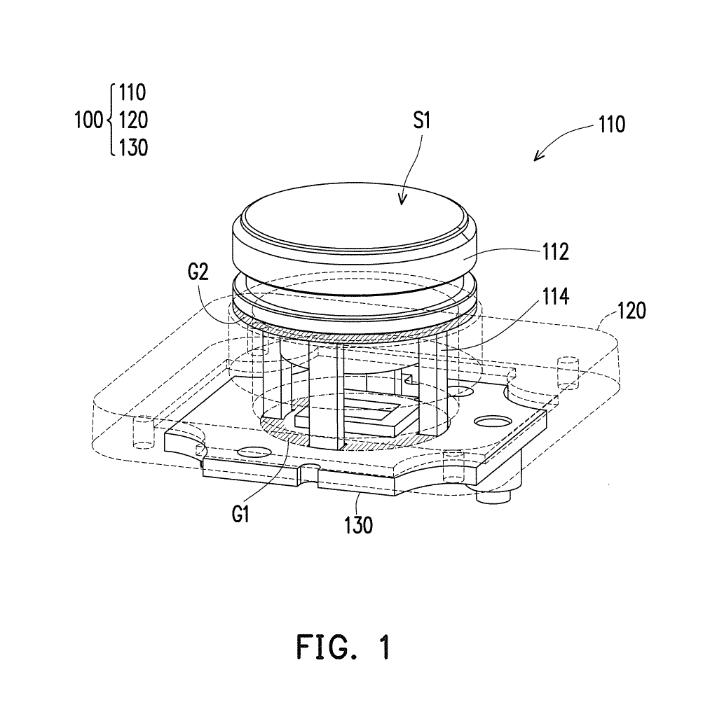

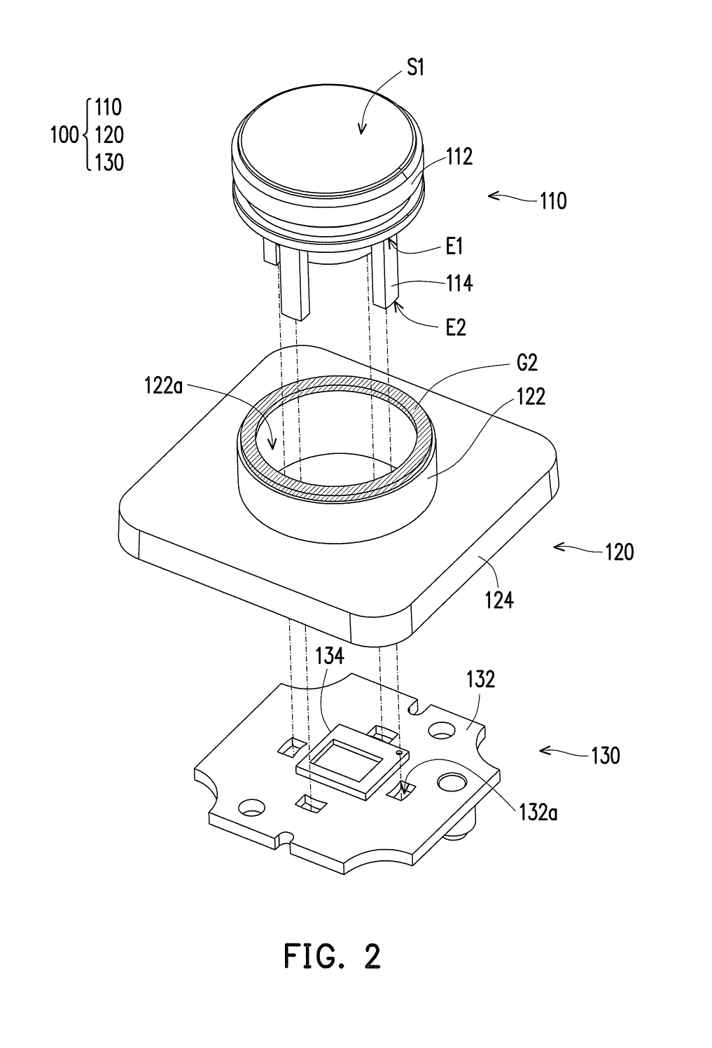

FIG. 1 is a schematic view illustrating a lens assembly according to an embodiment of the invention. FIG. 2 is an exploded view illustrating the lens assembly in FIG. 1. Some components in FIG. 1 are shown in dotted lines, so as to clearly illustrate correlations of the components. With reference to FIG. 1 and FIG. 2, in the present embodiment, a lens assembly 100 includes a lens module 110, a housing 120, a first adhesive G1, and a circuit board module 130. The lens module 110 includes an external structural element and an optical lens located in the external structural element. The optical lens has an image capturing surface S1 for collecting light, so as to generate images. The structural element is substantially divided into a top portion 112 and a stand 114. The top portion 112 accommodates the optical lens. The stand 114 has a first end E1 and a second end E2 opposite to each other, the first end E1 is connected to the top portion 112, and the second end E2 extends from the top portion 112. Here, the stand 114 refers to four pillars located below the top portion 112.

The housing 120 includes a substrate 124, a protruding portion 122 located on the substrate 124, and a hole 122a penetrating the protruding portion 122 and the substrate 124. The stand 114 of the lens module 110 passes through the hole 122a and is assembled to the circuit board module 130, such that the housing 120 is substantially located between the circuit board module 130 and the top portion 112 of the lens module 110 after said assembling process is performed. Note that the stand 114 of the lens module 110 is structurally assembled to the circuit board module 130; hence, the housing 120, the circuit board module 130, and the stand 114 can be adhered by a first adhesive G1 through performing an underfill packaging technique and can then be packaged and fixed. As such, packaging and fixing said structure can be done through only one manufacturing process. For illustrative purposes, the first adhesive G1 in FIG. 1 is depicted in a planar (two-dimensional) manner.

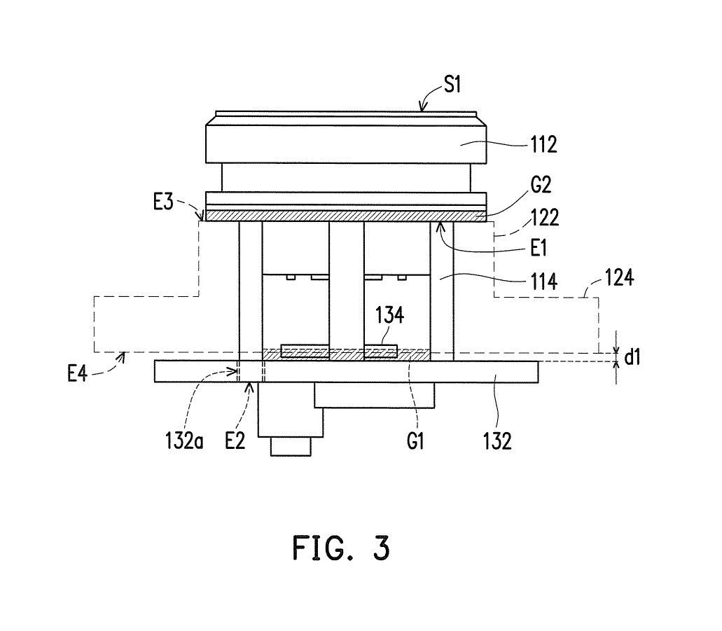

FIG. 3 is a lateral view illustrating the lens assembly in FIG. 1. With reference to FIG. 1 to FIG. 3, the circuit board module 130 includes a circuit board 132 and an image sensor 134 packaged on the circuit board 132 through a ball grid array (BGA) technique, for instance. The circuit board 132 has a plurality of blind holes 132a surrounding the image sensor 134 and corresponding to the stand 114, i.e., the stand 114 passes through the hole 122a, and the second end E2 of the stand 114 is inserted into the corresponding blind hole 132a. Thereby, the optical lens located at the top portion 112 faces the image sensor 134 on the circuit board 132 through the hole 122a, and the image generated through collecting light by the image capturing surface S1 can be captured.

Meanwhile, the top portion 112 of the lens module 110 is adhered to the upper edge E3 of the housing 120 (the protruding portion 122) through the second adhesive G2. After the lens module 110 and the housing 120 are adhered to each other, a portion of the stand 114 exposed by the housing 120 (i.e., the second end E2) has a height that is greater than the depth of the blind holes 132a; hence, a gap d1 exists between a lower edge E4 of the housing 120 (the substrate 124) and the circuit board 132. Thereby, in the underfill packaging process, an attaching space formed by the stand 110, the substrate 124 of the housing 120, and the circuit board 132 can be filled with the first adhesive G1 through the gap dl, and the first adhesive G1 is surrounded by the stand 114. The first adhesive G1 also surrounds the image sensor 134 and covers a packaging area connecting the image sensor 134 and the circuit board 132, so as to effectively protect the image sensor 134. The blind holes 132a allow the first adhesive G1 filling the attaching space to be overflowed and prevent the first adhesive G1 from overflowing from the attaching space on the circuit board module 130.

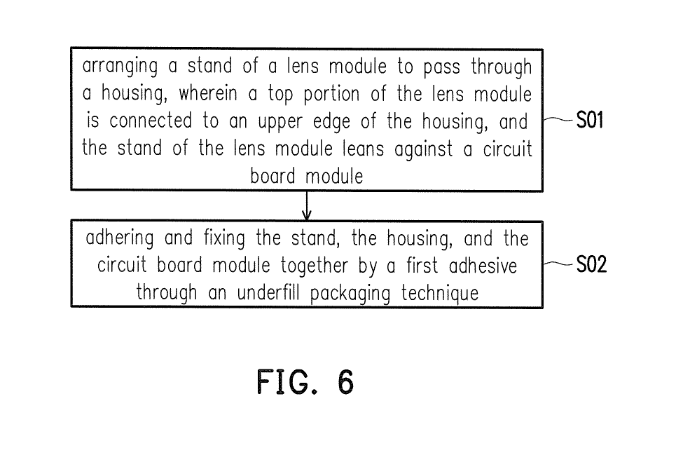

FIG. 6 is a flowchart showing a manufacturing method of a lens assembly according to an embodiment of the invention. With reference to FIG. 6, steps of assembling components of said lens assembly are described below.

In step S01, the stand 114 of the lens module 110 is arranged to pass through the housing 120. Here, the top portion 112 of the lens module 110 is connected to the upper edge of the housing 120, and the stand 114 of the lens module 110 leans against the circuit board module 130.

Specifically, in this step, the optical lens and an external structure are combined to form the lens module 110. The stand 114 of the lens module 110 passes through the hole 122a of the housing 120 and is adhered between the upper edge E3 (show in FIG. 3) of the housing 120 and the top portion 112 of the lens module 110 by the second adhesive G2. Here, the second adhesive G2 is, for instance, photo-sensitive resin ultraviolet glue) which can be cured by light, so as to achieve the required adhesion effects. So far, the initial assembly of the lens module 110 and the housing 120 is completed. It should be mentioned that the second adhesive G2 is in a pre-curing state, i.e., there is still allowance of relative movement between the lens module 110 and the housing 120, which is conducive to subsequent minor modifications.

After that, the second end E2 of the stand 114 is inserted into the corresponding blind holes 132a on the circuit board 132, and the gap d1 is formed between the lower edge E4 of the housing 120 and the circuit board 132.

In step S02, the stand 114, the housing 120, and the circuit board module 130 are adhered and fixed together by the first adhesive G1 through the underfill packaging technique.

Particularly, in this step, the attaching space formed by the stand 110, the housing 120, and the circuit board 132 is filled with the first adhesive G1 through the gap d1, such that the first adhesive G1 is in contact with and completely fills the attaching space. The attaching space is surrounded by the stand 114 and encapsulates the packaging area between the image sensor 134 and the circuit board 132. At this time, optical modifications between the lens module 110 and the image sensor 134 on the circuit board 132 are made. Owing to the allowance of relative movement between the lens module 110 and the housing 120, the lens module 110 and the housing 120 can be well assembled and aligned in this step.

At last, the first adhesive G1 is cured (e.g., through heating or the like, which should not be construed as a limitation to the invention), and the assembly of the lens module 110, the housing 120, and the circuit board module 130 is completed. In light of the foregoing, the lens module 110, the housing 120, and the circuit board module 130 can be fixed at one time through the underfill packaging technique. Prior to this step, the optical modifications between the lens module 110 and the image sensor 134 are completed. Thereby, in the assembling process, the optical performance is not lessened by repeatedly stacking components.

In the present embodiment, it should also be mentioned that an orthogonal projection of the stand 114 on the circuit board module 130 has an open profile, i.e., the stand 114 does not have a closed structure, whereby it is easier to introduce the first adhesive G1 during the underfill packaging process.

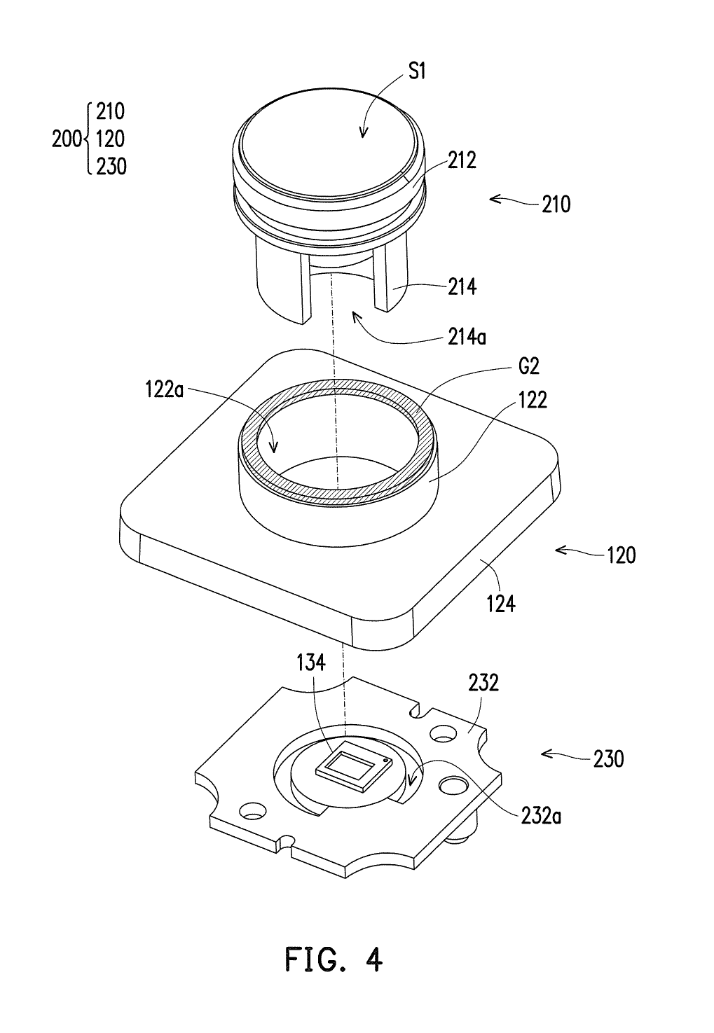

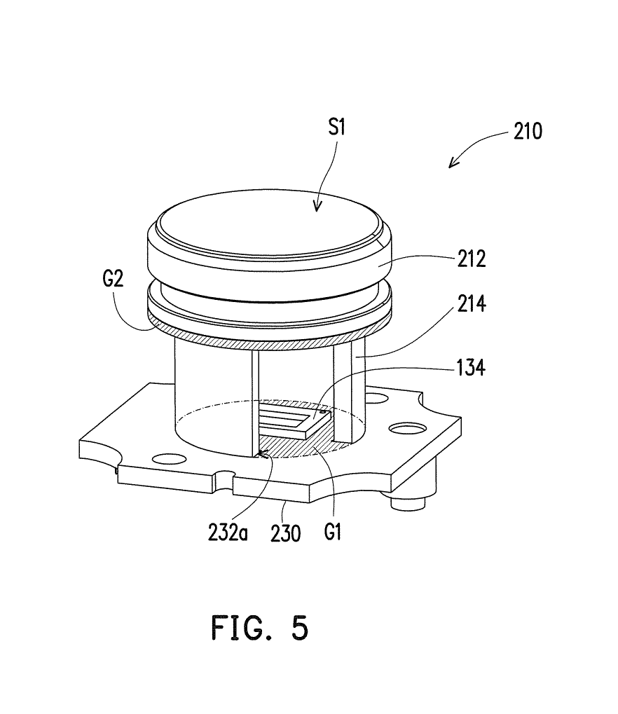

FIG. 4 is an exploded view illustrating a lens module according to another embodiment of the invention. FIG. 5 is a schematic view illustrating some components of the lens assembly in FIG. 4. Here, the housing is limited, such that other relevant components can be clearly illustrated. With reference to FIG. 4 and FIG. 5, different from the lens assembly provided in the previous embodiment, the lens assembly 200 provided in the present embodiment includes a top portion 212 identical to that discussed above for accommodating the optical lens and exposing the image capturing surface S1 and a stand 214. The stand 214 is a wall extending from the top portion 212, and the circuit board 232 of the circuit board module 230 correspondingly has a blind hole 232a. The wall is correspondingly assembled to the blind hole 232a.

The stand 214 has a breach 214a that has open, circular profile on a virtual plane where the circuit board module 230 is located, and thereby the blind hole slot 232a having the profile can be matched with the stand 214.

Since the assembly of the lens module 210 and the housing 120 is the same as that provided in the previous embodiment, no further explanation is provided hereinafter. During the underfill packaging process, the first adhesive G1 is introduced into the attaching space via the breach 214a through the gap (as shown in FIG. 3 and provided in the previous embodiment), and the attaching space is surrounded by the stand 214 in form of a wall. As such, the lens module 210, the housing 120, and the circuit board 230 provided in the present embodiment can achieve the same adhesion effects as those accomplished in the previous embodiment.

In all the previous embodiments, the image sensor 134 is packaged on the circuit board 132 through the BGA technique, for instance. That is, the image sensor 134 and the circuit board 132 may be electrically connected through tin balls therebetween, for instance. The BGA technique is known to people having ordinary skill in the art and thus will not be further explained hereinafter. Note that the image quality may still be deteriorated if the BGA packaged structure is cracked due to vibrations, external environmental variations, or manufacturing variations. Therefore, in the present embodiment, the adhesion effects can be achieved through the underfill packaging process, and the underfill packaging process can be applied to further isolate the tin balls from the external environment, so as to better protect the tin balls. At the same time, after assembly, the housing, the circuit board module, and the lens module can have the enhanced overall structural strength after the first adhesive is cured.

To sum up, according to the previous embodiments, the lens assembly has the stand that can pass through the housing and can be assembled to the circuit board module. Hence, when the underfill packaging process is performed on the circuit board module, the lens module, the housing, and the circuit board module can be fixed simultaneously by the first adhesive. Thereby, assembly tolerance resulting from stacking components can be effectively prevented, and the assembly process can be effectively simplified. As a result, the lens assembly with the simple structure can have favorable optical performance.

The stand may be in form of a pillar or a wall and has a non-closed profile on a virtual plane where the circuit board module is located. Hence, in the underfill packaging process, the first adhesive can be well introduced into the attaching space, and the manufacturing process can be smoothly performed.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

What is claimed is:

1. A lens assembly comprising:
a lens module having a top portion and a stand extending from the top portion;
a housing having an upper edge connected to the top portion of the lens module, wherein the stand of the lens module passes through the housing;
a circuit board module connected to the stand, wherein the housing is located between the top portion of the lens module and the circuit board module; and
a first adhesive configured to fix the stand, the housing and the circuit board module.

2. The lens assembly according to claim 1, further comprising a second adhesive disposed between the top portion of the lens module and the upper edge of the housing.

3. The lens assembly according to claim 1, wherein the circuit board module comprises a circuit board, a gap is formed between a lower edge of the housing and the circuit board, and the first adhesive is filled into an attaching space formed by the stand, the housing, and the circuit board through the gap.

4. The lens assembly according to claim 3, wherein the circuit board module further comprises an image sensor disposed on the circuit board, the top portion of the lens module faces the image sensor through a hole of the housing, and the image sensor is disposed in the attaching space.

5. The lens assembly according to claim 1, wherein an orthogonal projection of the stand on the circuit board module has an open profile.

6. The lens assembly according to claim 1, wherein the stand comprises a plurality of pillars extending from the top portion, the circuit board module has a plurality of blind holes, and the pillars are respectively assembled into the blind holes.

7. The lens assembly according to claim 6, wherein an area located on the circuit board module and surrounded by the pillars is filled with the first adhesive.

8. The lens assembly according to claim 1, wherein the stand is a wall extending from the top portion, the circuit board module has a blind slot, and the wall is assembled to the blind slot.

9. The lens assembly according to claim 8, wherein the stand has a breach, and an area located on the circuit board module and surrounded by the stand is filled with the first adhesive through the breach.

10. A manufacturing method of a lens module configured to manufacture the lens assembly according to claim 1, the manufacturing method comprising:
arranging the stand of the lens module to pass through the housing, wherein the top portion of the lens module is connected to the upper edge of the housing, and the stand of the lens module leans against the circuit board module; and
fixing the stand and the housing on the circuit board module by the first adhesive through an underfill packaging technique.

11. The manufacturing method according to claim 10, further comprising:
arranging an image sensor on a circuit board through a ball grid array technique to form the circuit board module.

12. The manufacturing method according to claim 10, further comprising:
when the stand passes through the housing, the top portion and the upper edge of the housing are adhered by a second adhesive.

13. The manufacturing method according to claim 12, wherein the top portion and the upper edge of the housing are adhered by the second adhesive through a pre-curing technique.

14. The manufacturing method according to claim 10, wherein the stand comprises a plurality of pillars extending from the top portion, and the manufacturing method further comprises:
filling the first adhesive into an area located on the circuit board module and surrounded by the pillars when the underfill packaging technique is performed.

15. The manufacturing method according to claim 10, wherein the stand has a breach, and the manufacturing method further comprises:
filling the first adhesive into an area located on the circuit board module and surrounded by the stand through the breach when the underfill packaging technique is performed.
